(19) United States
(12) Patent Application Publication
(10) Pub. No.: US 2024/0371790 A1
(43) Pub. Date: Nov. 7, 2024

(54) SEMICONDUCTOR DEVICE AND METHOD FORMING THE SAME

(71) Applicant: Winbond Electronics Corp., Taichung City (TW)

(72) Inventors: Yi-Chi TSAI, Tainan City (TW); Jiun-Sheng YANG, Taichung City (TW)

(21) Appl. No.: 18/458,633

(22) Filed: Aug. 30, 2023

(30) Foreign Application Priority Data
May 2, 2023 (TW) 112116280

(51) Int. Cl. H01L 23/00; H01L 21/768; H01L 23/48

(52) U.S. Cl. CPC H01L 23/562; H01L 21/76898; H01L 23/481

(57) ABSTRACT

A semiconductor device includes: a substrate; a source region and a drain region disposed in the substrate; a shallow trench isolation (STI) region disposed in the substrate and surrounding the source region and the drain region; a plurality of through substrate vias (TSV) through the substrate, wherein the plurality of through substrate vias are adjacent to the shallow trench isolation region; and a compound semiconductor structure isolating the shallow trench isolation region from the plurality of through substrate vias. The plurality of through substrate vias have a first stress type, and the compound semiconductor structure has a second stress type different from the first stress type.

### CROSS REFERENCE TO RELATED APPLICATIONS

This application claims priority of Taiwan Patent Application No. 112116280, filed May 2, 2023, the entirety of which is incorporated by reference herein.

### BACKGROUND OF THE INVENTION

### Field of the Invention

The present disclosure relates to a semiconductor device and a method forming the same, and in particular, to a compound semiconductor structure and a method forming the same.

### Description of the Related Art

In recent years, new configurations for 3D integrated circuits have been explored in order to further increase the functional density of semiconductor integrated circuits (ICs). In order to achieve an effective electrical connection in a 3D integrated circuit, a plurality of through substrate vias (TSV) may extend into the substrate from the frontside surface of the substrate, and may be exposed from the backside surface of the substrate. However, because the plurality of through substrate vias have tensile stress, other devices in the semiconductor integrated circuit may be impacted.

For example, since the conducting current of the n-type metal-oxide semiconductor (MOS) and the conducting current of the p-type metal-oxide semiconductor are impacted differently by tensile stress and compressive stress, the conducting current may be mis-matched between the n-type metal-oxide semiconductor and the p-type metal-oxide semiconductor due to the plurality of through substrate vias. Specifically, when the semiconductor device has both an n-type metal-oxide semiconductor and a p-type metal-oxide semiconductor, the tensile stress from the plurality of through substrate vias may increase the conducting current of the n-type metal-oxide semiconductor, but it may also decrease the conducting current of the p-type metal-oxide semiconductor, which results in a current mis-match between the n-type metal-oxide semiconductor and the p-type metal-oxide semiconductor.

In the conventional circuit design, the plurality of through substrate vias may be gathered together, and the plurality of through substrate vias are isolated from other semiconductor elements by a space (for example, the keep out zone (KOZ)) to lower the impact on other semiconductor elements. Typically, when the plurality of through substrate vias are isolated from the other elements by a space that is greater than or equal to the defined keep out zone, the impact of stress from the plurality of through substrate vias on other elements may be minimized. For example, through the disposition of the keep out zone, a superior current match between the n-type metal-oxide semiconductor and the p-type metal-oxide semiconductor may be obtained. However, the disposition of the keep out zone may increase the area required in the circuit design, and the benefit from applying the 3D integrated circuit (such as lowering the occupied circuit area) may thus be neutralized.

### BRIEF SUMMARY OF THE INVENTION

An embodiment of the present disclosure provides a semiconductor device, the semiconductor device includes a substrate; a source region and a drain region disposed in the substrate; a shallow trench isolation (STI) region disposed in the substrate and surrounding the source region and the drain region; a plurality of through substrate vias (TSV) through the substrate, wherein the plurality of through substrate vias are adjacent to the shallow trench isolation region; and a compound semiconductor structure isolating the shallow trench isolation region from the plurality of through substrate vias. The plurality of through substrate vias have a first stress type, and the compound semiconductor structure has a second stress type different from the first stress type.

Another embodiment of the present disclosure provides a method forming a semiconductor device, the method includes providing a substrate; forming a shallow trench isolation region, a source region, and a drain region in the substrate; forming an expanded trench in the substrate; filling a compound semiconductor structure into the expanded trench; and forming a plurality of through substrate vias extending into the substrate from above a frontside surface of the substrate. The shallow trench isolation region surrounds the source region and the drain region. The expanded trench is isolated from the source region and the drain region by the shallow trench isolation region. The compound semiconductor structure surrounds the plurality of through substrate vias. The plurality of through substrate vias have a first stress type, and the compound semiconductor structure has a second stress type different from the first stress type.

### BRIEF DESCRIPTION OF THE DRAWINGS

The present disclosure can be more fully understood by reading the subsequent detailed description and examples with references made to the accompanying drawings, wherein:

FIGS. 1-20 illustrate cross-sectional views of various intermediate stages of forming a semiconductor device, according to some embodiments of the present disclosure.

FIG. 21 illustrates a top view of the semiconductor device, according to some embodiments of the present disclosure.

FIG. 22 illustrates a cross-sectional view of a semiconductor device, according to other embodiments of the present disclosure.

### DETAILED DESCRIPTION OF THE INVENTION

The semiconductor device of the present disclosure introduces an innovative compound semiconductor structure between a plurality of through substrate vias (TSV) and other elements.

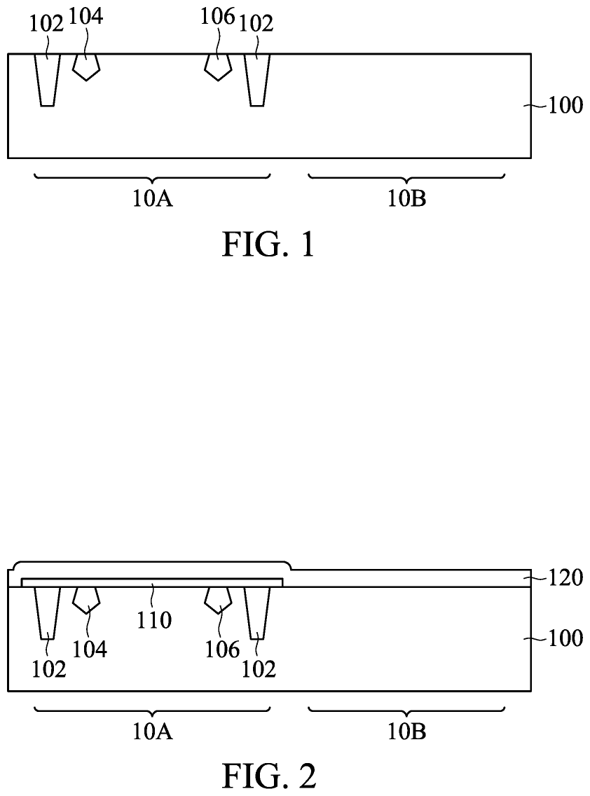

FIGS. 1-20 illustrate cross-sectional views of various intermediate stages of forming a semiconductor device 10, according to some embodiments of the present disclosure. In some embodiments, the semiconductor device 10 may include any number of active components and passive components, which are omitted and not illustrated herein.

Referring to FIG. 1, the semiconductor device 10 of the present disclosure may be compartmentalized into a device area 10A and a peripheral area 10B. In subsequent processes, metal-oxide semiconductors (p-type or n-type) may be formed in the device area 10A, while a plurality of through substrate vias and a compound semiconductor structure may be formed in the peripheral area 10B. An initial structure of the semiconductor device 10 may include a substrate 100, a shallow trench isolation (STI) region 102, a source region 104, and a drain region 106. The substrate 100 may be, for example, a wafer or a chip. In an embodiment, the substrate 100 may be a semiconductor substrate, (such as a silicon (Si) substrate or a germanium (Ge) substrate), a compound semiconductor substrate (including gallium nitride (GaN), silicon carbide (SiC), gallium arsenide (GaAs), gallium phosphide (GaP), indium phosphide (InP), indium arsenide (InAs), indium antimonide (InSb), or a combination thereof), an alloy semiconductor (such as silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, gallium indium arsenide phosphide (GaInAsP) alloy, or a combination thereof). In other embodiments, the substrate 100 may also be a semiconductor on insulator (SOI) substrate.

The device area 10A may have the shallow trench isolation region 102, the source region 104, and the drain region 106. The shallow trench isolation region 102 may define the boundary of the active area, and may electrically isolate active area elements within or above the substrate 100. In other embodiments, the shallow trench isolation region 102 may also be replaced by a deep trench isolation (DTI) region, a local oxidation of silicon (LOCOS) structure, or the like.

The source region 104 and the drain region 106 may be extended from the frontside surface of the substrate 100 into the substrate 100. In an embodiment, the source region 104 and the drain region 106 may be n-type or p-type. The depths of the source region 104 and the drain region 106 within the substrate 100 may be between 20 nm and 100 nm. The source region 104 and the drain region 106 may be formed by for example, ion implantation, diffusion process, in-situ doping, or the like.

Referring to FIG. 2, a passivation layer 110 and a pad oxide layer 120 may be sequentially formed on the frontside surface of the substrate 100. The passivation layer 110 may only cover the device area 10A, while the pad oxide layer 120 may cover both the device area 10A and the peripheral area 10B. Materials of the passivation layer 110 may include silicon oxide (SiO), silicon nitride (SiN), silicon carbide, silicon oxynitride (SiON), silicon oxynitrocarbide (SiONC), or the like. Materials of the pad oxide layer 120 may include oxides. The passivation layer 110 and the pad oxide layer 120 may be formed by chemical vapor deposition (CVD). Since the subsequent etching process may completely consume the pad oxide layer 120, the disposition of the passivation layer 110 may ensure the device area 10A from being damaged by the subsequent etching process. In other embodiments, the passivation layer 110 may be omitted, and only the pad oxide layer 120 may be disposed on the substrate 100.

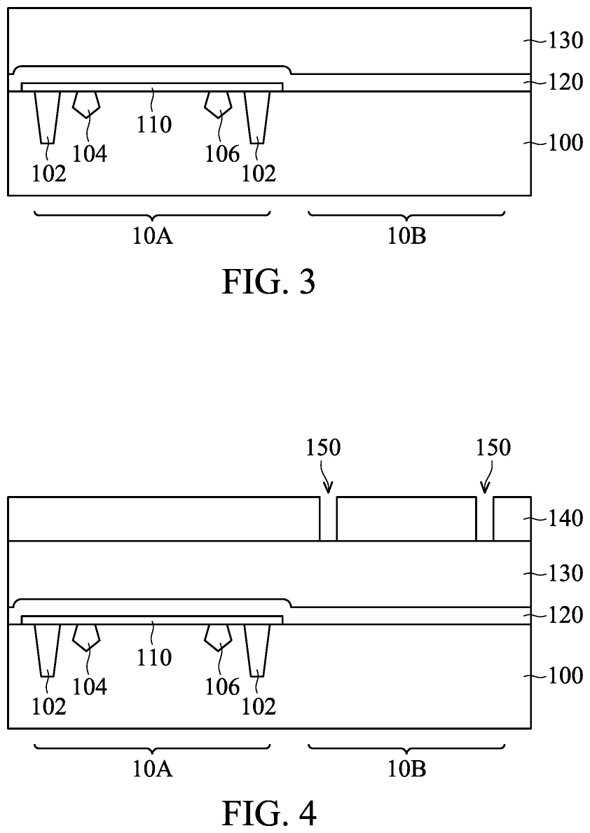

Referring to FIGS. 3 and 4, a hard mask layer 130 may be formed on the pad oxide layer 120, and a patterned photoresist layer 140 may be formed on the hard mask layer 130. The hard mask layer 130 may be formed for example by a deposition process, while the patterned photoresist layer 140 may be formed by a deposition process, a lithography process, and an etching process. As shown in FIG. 4, the patterned photoresist layer 140 has an opening 150.

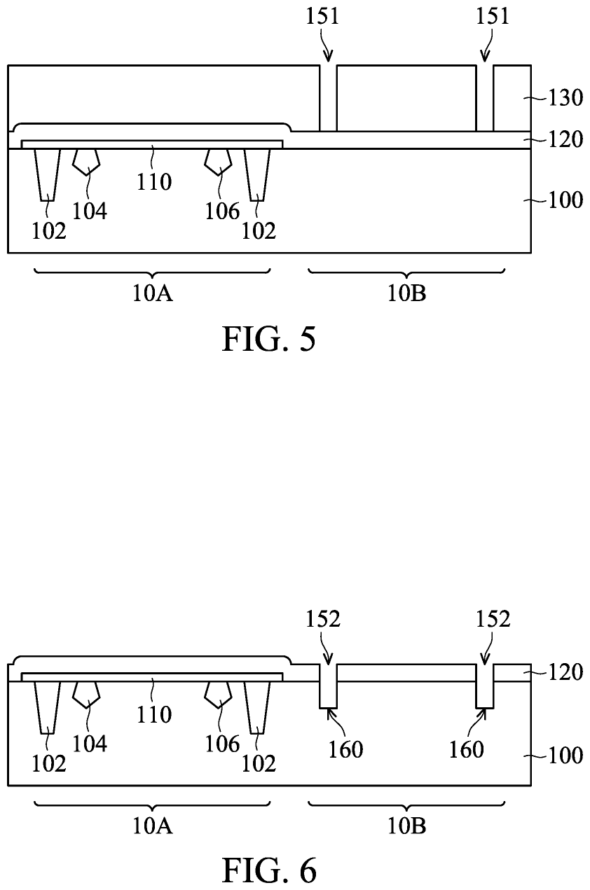

Referring to FIG. 5, the pattern of the patterned photoresist layer 140 may be transferred to the underlying hard mask layer 130 to form an opening 151. Specifically, the etching process may be performed on the hard mask layer 130 using the patterned photoresist layer 140 to form the opening 151. The etching process may include dry etch, wet etch, or the like. In an embodiment, the width of the opening 151 may be between 1 μm and 5 μm.

Referring to FIG. 6, the pattern of the hard mask layer 130 may be transferred to the underlying pad oxide layer 120 and the substrate 100 to form an opening 152 and an initial trench 160. For example, an etching process may be performed on the pad oxide layer 120 using the patterned hard mask layer 130 to form the opening 152, followed by performing an etching process on the substrate 100 using the patterned pad oxide layer 120 to form the initial trench 160. The initial trenches 160 may be extended from the frontside surface of the substrate 100 into the substrate 100, and the depth thereof may be between 1 μm and 5 μm. In the present embodiment, the disposition of the pad oxide layer 120 may alleviate the stress of the substrate 100.

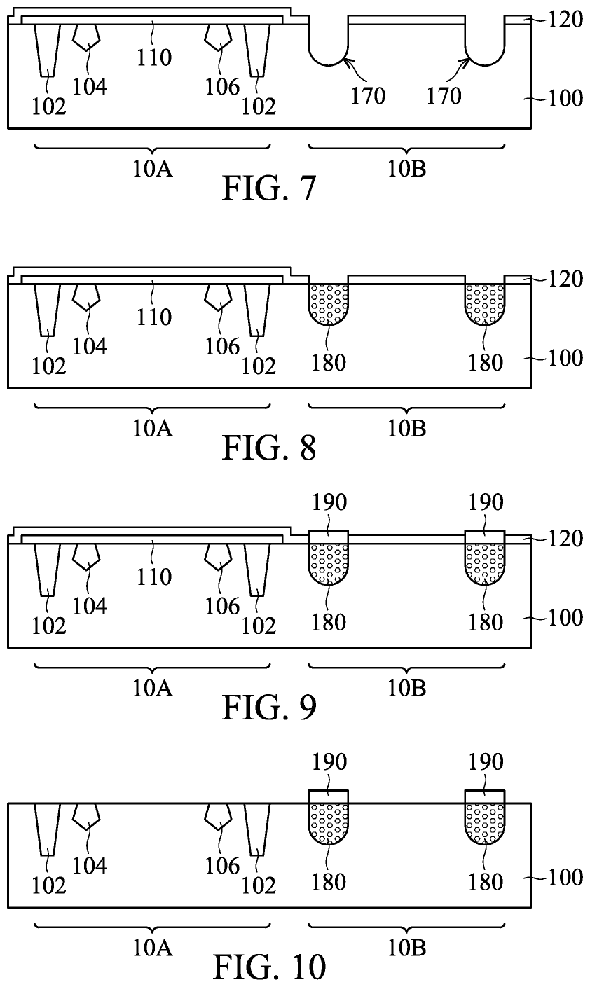

Referring to FIG. 7, an isotropic etching process may then be performed on the initial trench 160, so the initial trench 160 may be further expanded into an expanded trench 170. For example, the isotropic wet etch process may be performed by dip wash, spray wash, the like, or a combination thereof. The width of the expanded trench 170 may be between 1 μm and 5 μm. The depth of the expanded trench may be between 1 μm and 5 μm. It should be noted that in addition to expanding the initial trench 160, the wet etch process may further reduce the remaining thickness of the pad oxide layer 120.

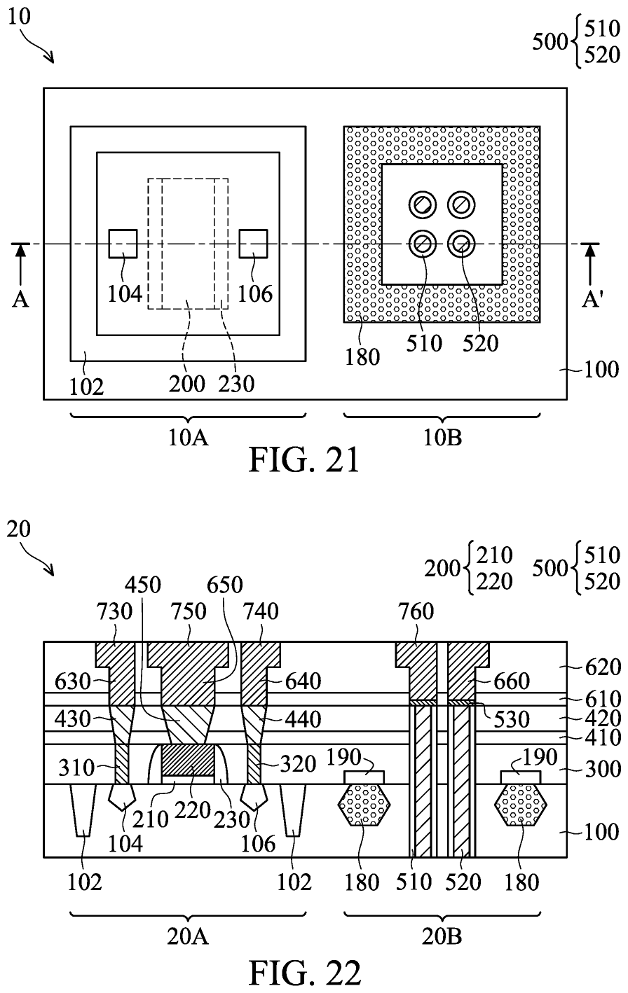

From top view (in reference with FIG. 21), the expanded trench 170 in the peripheral area 10B is a ring structure that surrounds the subsequently formed plurality of through substrate vias. It should be specifically explained that the conditions of the wet etch process may be controlled, so the expanded trench 170 may be designed into the desired profile. The subsequently formed compound semiconductor structure may more effectively eliminate the impact of the stress of the plurality of through substrate vias toward other elements.

In an embodiment, etchants of the wet etch process may include ammonium hydroxide (NH₄OH), diluted hydrofluoric acid (DHF), tetra methyl ammonium hydroxide (TMAH), ammonia (NH₃), ethylenediamine pyrocatechol (EDP), nitric acid (HNO₃), acetic acid (CH₃COOH), potassium hydroxide (KOH), or a combination thereof. In a specific embodiment, the wet etch process may be performed using tetra methyl ammonium hydroxide, followed by performing rinsing with diluted hydrofluoric acid. In the present embodiment, the etching conditions (for example, the concentration, the process time, the cycles, or the like) of using tetra methyl ammonium hydroxide may be designed, so the resulting profile of the expanded trench 170 may appear to be U-shape.

Referring to FIG. 8, a compound semiconductor structure 180 may be formed in the expanded trench 170. Furthermore, the compound semiconductor structure 180 may adopt the profile of the expanded trench 170, and thus may have the U-shape profile. The width and the depth of the compound semiconductor structure 180 may be similar to those of the expanded trench 170, and the details are not described again herein to avoid repetition.

From top view, since the expanded trench 170 is designed into the ring structure, the compound semiconductor structure 180 formed within the substrate 100 may also appear as the ring structure that surrounds the subsequently formed plurality of through substrate vias. In other words, the plurality of through substrate vias may be isolated from other elements in the substrate 100 by the compound semiconductor structure 180. As mentioned previously, since the plurality of through substrate vias have the tensile stress (the first stress type), the compound semiconductor structure 180 may have the compressive stress (the second stress type). The compressive stress of the compound semiconductor structure 180 and the tensile stress of the plurality of through substrate vias may be neutralized by each other, which in turn may eliminate the stress of the plurality of through substrate vias from omnidirectionally impacting other elements within the substrate 100.

In an embodiment, materials of the compound semiconductor structure 180 may include compound semiconductor, for example silicon germanium or the like. Silicon germanium may be considered as doping extrinsic germanium atoms into intrinsic silicon atoms (which may have the same material as the substrate 100). Since the mass of the germanium atoms is larger than the mass of the silicon atoms, the second stress type may thus be generated. In other embodiments, boron (B) may be further doped into silicon germanium to form a tertiary compound of boron-doped silicon germanium. It should be appreciated that conventionally, doped silicon germanium may be widely used in logic fab mainly to help enhancing the electron-hole mobility in the active components. For example, the compound semiconductor may include doped silicon germanium and undoped silicon germanium lining on the surface of doped silicon germanium. However, the dopants may not significantly alter the second stress type of silicon germanium, thus doping is not a necessary procedure. The compound semiconductor structure 180 may be formed by any suitable deposition process.

Referring to FIG. 9, a cap layer 190 may be formed on the compound semiconductor structure 180. The cap layer 190 may be formed by any suitable deposition method. Materials of the cap layer 190 may be similar to those of the substrate 100, for example silicon or the like. The thickness of the cap layer 190 may be between 20 nm and 200 nm. The cap layer 190 may seal the compound semiconductor structure 180 within the substrate 100 to prevent the compound semiconductor structure 180 from being affected by subsequent processes. Since the former etching process has already reduced the pad oxide layer 120 into a very small thickness, the thickness of the cap layer 190 should be larger than the remaining thickness of the pad oxide layer 120, allowing the compound semiconductor structure 180 to be effectively sealed.

Referring to FIG. 10, after the cap layer 190 is formed, the passivation layer 110 and the pad oxide layer 120 may be removed. A suitable etching process may be performed using etchants that are etch selective to nitrides and oxides, so the passivation layer 110 and the pad oxide layer 120 may be removed, while the cap layer 190 may be preserved on the frontside surface of the substrate 100.

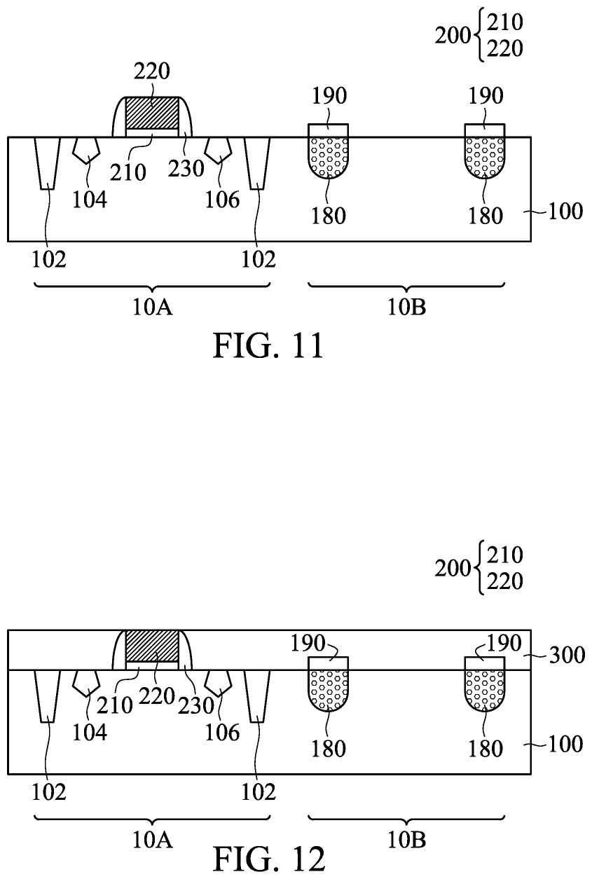

Referring to FIG. 11, a gate structure 200 may be formed in the device area 10A, followed by forming a gate spacer 230 on the sidewalls of the gate structure 200. For example, a gate dielectric layer and a gate electrode layer may be sequentially formed on the frontside surface of the substrate 100. The formation of the gate dielectric layer may include for example chemical vapor deposition, atomic layer deposition (ALD), or the like. The formation of the gate electrode layer may include for example physical vapor deposition (PVD), atomic layer deposition, plating, or the like. Next, the gate dielectric layer and the gate electrode layer may be patterned to form a gate dielectric 210 and a gate electrode 220, respectively. The patterning procedures may include lithography process and etching process. After that, a gate spacer layer may be conformally deposited on the frontside surface of the substrate 100, the sidewalls of the gate structure 200, and the top surface of the gate structure 200. Next, the horizontal portions of the gate spacer layer (including the portion on the substrate 100 and the portion on the top surface of the gate structure 200) may be etched by an anisotropic etch back process. The remaining portion of the gate spacer layer on the sidewalls of the gate structure 200 becomes the gate spacer 230.

As shown in FIG. 11, the gate structure 200 (including the gate dielectric 210 and the gate electrode 220) and the gate spacer 230 may sit on the frontside surface of the substrate 100, and may be laterally located between the source region 104 and the drain region 106. Materials of the gate dielectric 210 may include high-k dielectric materials (for example, materials with the dielectric constant larger than 7), for example hafnium (IV) oxide, hafnium silicate (HfSiO₄), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium (IV) oxide, titanium oxide (TiO), tantalum oxide (Ta₂O₅), yttrium oxide (Y₂O₃), silicon oxynitride, or the like. Materials of the gate electrode 220 may include amorphous silicon, polysilicon, poly-SiGe, metal nitride, metal silicide, metal carbide, metal oxide, metals, or the like. Metals may include cobalt (Co), ruthenium (Ru), aluminum (Al), palladium (Pd), platinum (Pt), tungsten (W), copper (Cu), titanium (Ti), tantalum (Ta), silver (Ag), gold (Au), nickel (Ni), the like, or a combination thereof.

Referring to FIG. 12, an interlayer dielectric (ILD) layer 300 may be formed on the frontside surface of the substrate 100. The interlayer dielectric layer 300 may surround the gate structure 200 and the gate spacer 230, while the top portions of the gate structure 200 and/or the gate spacer 230 may be exposed. For example, the dielectric material may be blanket deposited on the substrate 100, covering the cap layer 190 of the peripheral area 10B, and the gate structure 200 and the gate spacer 230 of the device area 10A. Next, chemical mechanical polish (CMP) or mechanical grinding may be performed on the dielectric material to expose the top portions of the gate structure 200 and/or the gate spacer 230. Materials of the interlayer dielectric layer 300 may include silicon oxide, silicon nitride, silicon carbide, silicon oxynitride, silicon oxynitrocarbide, tetra ethyl ortho silicate (TEOS), undoped silicate glass, doped silicon oxide, low-k dielectric materials, or the like. The thickness of the interlayer dielectric layer 300 may be similar to the overall thickness of the gate structure 200.

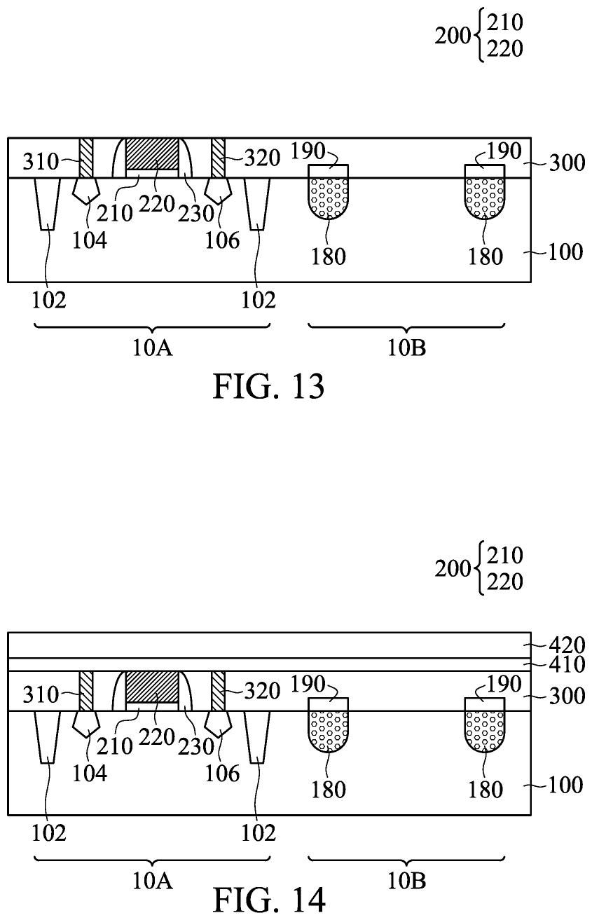

Referring to FIG. 13, after the interlayer dielectric 300 is formed, a source contact plug 310 and a drain contact plug 320 may be formed through the interlayer dielectric layer 300 in the device area 10A. For example, a plurality of openings may be formed in the interlayer dielectric layer 300 corresponding to the source region 104 and the drain region 106, followed by forming the source contact plug 310 and the drain contact plug 320 in the openings. Materials of the source contact plug 310 and the drain contact plug 320 may be similar to those of the gate electrode 220. In an embodiment, a barrier layer (not shown) may be formed between the source contact plug 310/the drain contact plug 320 and the sidewalls/the bottom of the openings, to prevent the materials of the source contact plug 310 and the drain contact plug 320 from diffusing into the interlayer dielectric layer 300. Materials of the barrier layer may include titanium nitride (TiN), titanium, tantalum, tantalum nitride (TaN), tungsten, tungsten nitride (WN), or a combination thereof. In an embodiment, the barrier layer may be formed by physical vapor deposition, atomic layer deposition, plating, or the like.

Referring to FIG. 14, an etch stop layer (ESL) 410 and an inter-metal dielectric (IMD) layer 420 may be sequentially formed on the interlayer dielectric layer 300. The etch stop layer 410 can prevent subsequent processes from damaging underlying elements, and the plasma of a backend process from affecting the frontend transistor. The inter-metal dielectric layer 420 may isolate the overlying metal materials from the underlying metal materials to avoid generating electrical short. Materials and formation of the etch stop layer 410 and the inter-metal dielectric layer 420 may be similar to those of the interlayer dielectric layer 300, and the details are not described again herein to avoid repetition. It should be noted that the selected material of the etch stop layer 410 should be etch selective to certain elements.

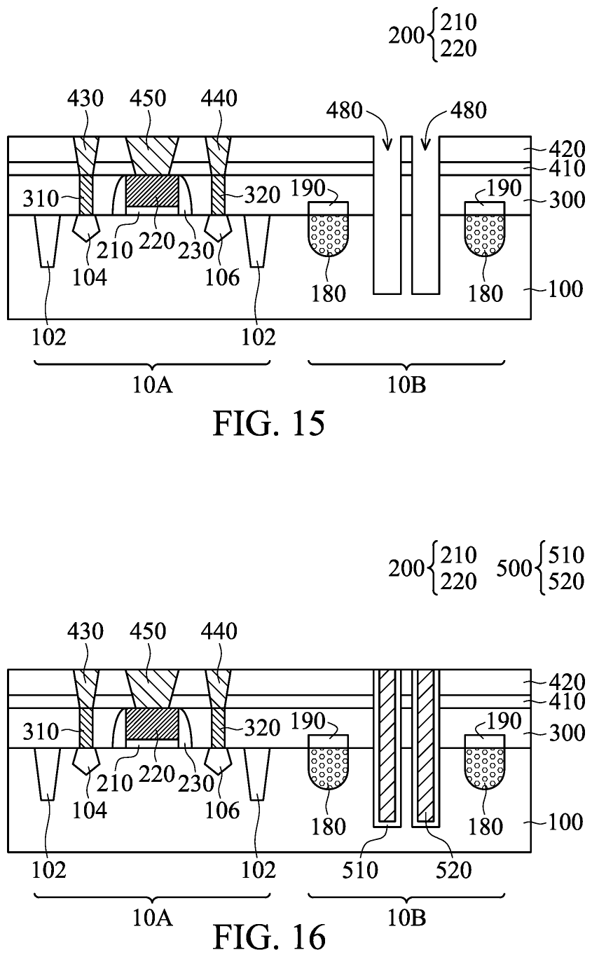

Referring to FIG. 15, a source contact via 430, a drain contact via 440, and a gate contact via 450 may be formed through the inter-metal dielectric layer 420 and the etch stop layer 410 in the device area 10A. The source contact via 430, the drain contact via 440, and the gate contact via 450 may be in physical contact with the source contact plug 310, the drain contact plug 320, and the gate structure 200, respectively. The materials and methods used to form the source contact via 430, the drain contact via 440, and the gate contact via 450 may be similar to those of the source contact plug 310 and the drain contact plug 320, and the details are not described again herein to avoid repetition.

Still referring to FIG. 15, after the inter-metal dielectric layer 420 is formed, a plurality of openings 480 may be formed through the inter-metal dielectric layer 420, the etch stop layer 410, and the interlayer dielectric layer 300, and may be extended into the substrate 100 in the peripheral area 10B. Although two of the openings 480 are illustrated in FIG. 15, but the present disclosure is not limited thereto. The peripheral area 10B may include any number of the openings 480, and may have the appropriate dimension and spacing. The width of the openings 480 may be between 1 μm and 20 μm. The formation of the plurality of openings 480 may be similar to that of the initial trench 160 and/or the expanded trench 170, and the details are not described again herein to avoid repetition.

Referring to FIG. 16, a plurality of through substrate vias 500 may be formed in the plurality of openings 480. For example, a diffuse barrier layer 510 may be conformally deposited on the bottom and the sidewalls of the plurality of openings 480, followed by depositing a conductive layer 520 filling the remaining openings 480. Next, chemical mechanical polish or mechanical grinding may be performed, so the top surface of the plurality of through substrate vias 500 is coplanar with the top surface of the inter-metal dielectric layer 420. As shown in FIG. 16, the plurality of through substrate vias 500 may include the diffuse barrier layer 510 and the conductive layer 520. The overall width of the plurality of through substrate vias 500 may be similar to the width of the plurality of openings 480. Materials of the diffuse barrier layer 510 and the conductive layer 520 may be similar to the materials of the gate dielectric 210 and the gate electrode 220, respectively.

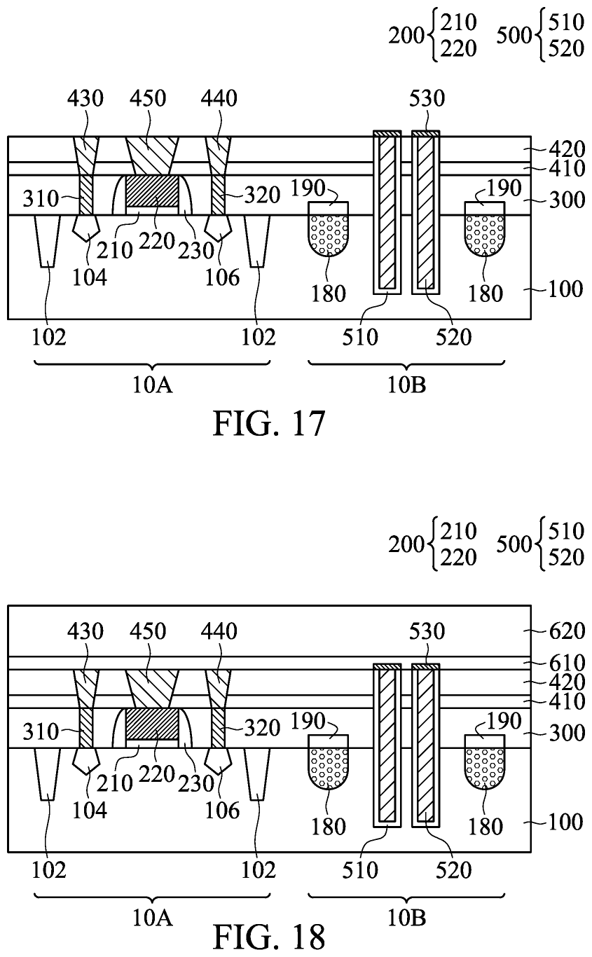

Referring to FIG. 17, a metal cap layer 530 may be formed on the plurality of through substrate vias 500. Although the metal cap layer 530 is illustrated as a single structure, but the present disclosure is not limited thereto. The metal cap layer 530 may be a composite structure including multiple layers. According to some embodiments of the present disclosure, the metal cap layer 530 may have excellent thermal stability, and may effectively control the topology of the plurality of through substrate vias 500 to prevent the extrusion of the conductive layer 520 that causes the occurrence of gaps in the vias, the generation of cracks in the dielectric material, and the thickness loss. Materials of the metal cap layer 530 may be similar to those of the gate electrode 220, such as a cobalt-based alloy. The metal cap layer 530 may be formed by any suitable deposition method.

Referring to FIG. 18, an etch stop layer 610 and an inter-metal dielectric layer 620 may be sequentially formed on the inter-metal dielectric layer 420 and the metal cap layer 530. The etch stop layer 610 covers the metal cap layer 530. The materials and methods used to form the etch stop layer 610 and the inter-metal dielectric layer 620 may be similar to those of the interlayer dielectric layer 300. It should be noted that one or more combinations of etch stop layer and inter-metal dielectric layer may be additionally interposed between the inter-metal dielectric layer 420 and the etch stop layer 610, depending on the application and design requirements.

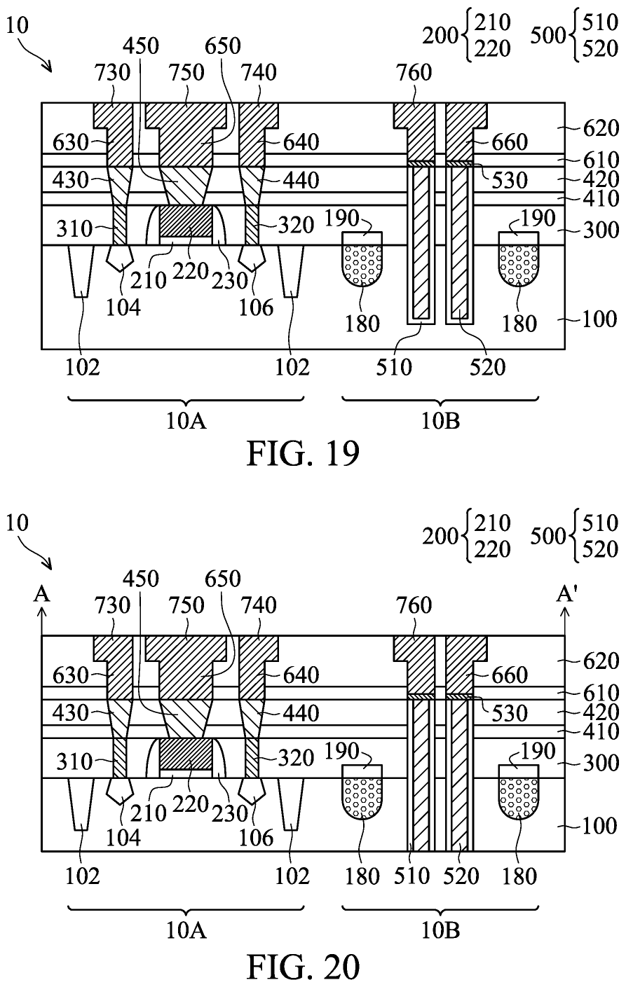

Referring to FIG. 19, a source metal via 630, a drain metal via 640, and a gate metal via 650 may be formed in the inter-metal dielectric layer 620, and may be extended through the etch stop layer 610 in the device area 10A. The source metal via 630, the drain metal via 640, and the gate metal via 650 may be in physical contact with the source contact via 430, the drain contact via 440, and the gate contact via 450, respectively. Furthermore, a source metal layer 730, a drain metal layer 740, and a gate metal layer 750 may be formed in the inter-metal dielectric layer 620. In an embodiment, the source metal layer 730 may be electrically coupled with the source region 104 through the source metal via 630, the source contact via 430, and the source contact plug 310. The drain metal layer 740 may be electrically coupled with the drain region 106 through the drain metal via 640, the drain contact via 440, and the drain contact plug 320. The gate metal layer 750 may be electrically coupled with the gate structure 200 through the gate metal via 650 and the gate contact via 450. The source metal layer 730, the drain metal layer 740, and the gate metal layer 750 may function as a source terminal, a drain terminal, and a gate terminal of the metal-oxide semiconductor transistor, respectively.

Still referring to FIG. 19, a substrate metal via 660 may be formed in the inter-metal dielectric layer 620, and may be extended through the etch stop layer 610 in the peripheral area 10B. The substrate metal via 660 may be in physical contact with the metal cap layer 530. In other embodiments, the substrate metal via 660 may be extended through the metal cap layer 530, and may be in physical contact with the plurality of through substrate vias 500. Furthermore, a substrate metal layer 760 may be formed in the inter-metal dielectric layer 620. In an embodiment, the substrate metal layer 760 may be electrically coupled with the plurality of through substrate vias 500 through the substrate metal via 660 and/or the metal cap layer 530. It should be appreciated that the source metal layer 730, the drain metal layer 740, the gate metal layer 750, and the substrate metal layer 760 may be considered as metal lines of the backend process.

The source metal via 630, the drain metal via 640, the gate metal via 650, the substrate metal via 660, the source metal layer 730, the drain metal layer 740, the gate metal layer 750, and the substrate metal layer 760 may be formed together, thus may include the same materials, which are similar to those of the gate electrode 220. First, a plurality of openings (including via openings and metal layer openings) may be formed in the etch stop layer 610 and the inter-metal dielectric layer 620 to correspond to the source contact via 430, the drain contact via 440, the gate contact via 450, and the plurality of through substrate vias 500 (or the metal cap layer 530), respectively. Next, the aforementioned materials may be filled into the plurality of openings through a suitable deposition process or a damascene process to form the source metal via 630, the drain metal via 640, the gate metal via 650, the substrate metal via 660, the source metal layer 730, the drain metal layer 740, the gate metal layer 750, and the substrate metal layer 760.

Referring to FIG. 20, the substrate 100 may be thinned from the backside surface of the substrate 100 until the bottom of the plurality of through substrate vias 500 is exposed in the peripheral area 10B, and the semiconductor device 10 of the present disclosure has completed. The substrate 100 may be thinned by a Taiko grinding process, a non-Taiko grinding process, or the like.

FIG. 21 illustrates a top view of the semiconductor device 10, according to some embodiments of the present disclosure. It should be noted that FIG. 20 is the cross-sectional view obtained from a line A-A′ of FIG. 21. FIG. 21 only illustrates the frontside surface of the substrate. The corresponding locations of the gate structure 200 and the gate spacer 230 are labelled in dash lines. For illustration purpose, only the shallow trench isolation region 102, the source region 104, the drain region 106, the gate structure 200, the gate spacer 230, the compound semiconductor structure 180, and the plurality of through substrate vias 500 are illustrated, while other elements are omitted.

Referring to FIG. 21, the shallow trench isolation region 102 of the device area 10A defines the active area (such as the metal-oxide semiconductor transistor constituted by the source region 104, the drain region 106, the gate structure 200, and the gate spacer 230), while the compound semiconductor structure 180 of the peripheral area 10B surrounds the plurality of through substrate vias 500. As mentioned previously, the compound semiconductor structure 180 of the present disclosure may have the compressive stress (the second stress type), which generates the neutralized effect toward the tensile stress (the first stress type) of the plurality of through substrate vias 500, in order to prevent the stress of the plurality of through substrate vias 500 from omnidirectionally impacting other elements within the substrate 100. Furthermore, due to the disposition of the compound semiconductor structure 180, the plurality of through substrate vias 500 may no longer need to maintain an excessively large distance with the device area 10A to prevent impacting the metal-oxide semiconductor transistor, which in turn lowers the required circuit area of the overall chip. Although the compound semiconductor structure 180 is illustrated as a square-shape ring herein, but the present disclosure is not limited thereto. The compound semiconductor structure 180 may have the ring structure of any suitable geometrical shape.

FIG. 22 illustrates a cross-sectional view of a semiconductor device 20, according to other embodiments of the present disclosure. The semiconductor device 20 may be compartmentalized into a device area 20A and a peripheral area 20B. The present embodiment is similar to the embodiment shown in FIG. 20, except the compound semiconductor structure 180 of the peripheral area 20B may have a hexagon-shape profile. In the present embodiment, the expanded trench 170 with the hexagon-shape profile may be formed by adjusting the wet etch conditions (in reference with FIG. 7), so the compound semiconductor structure 180 may have the hexagon-shape profile. In other embodiments, the wet etch conditions may be further adjusted, so the expanded trench 170 and the compound semiconductor structure 180 may have a rhombus-shape, a diamond-shape, or other polygon-shape profiles.

It is worth mentioned that when the compound semiconductor structure 180 has the U-shape profile herein, the second stress type may be distributed across the sidewalls of the compound semiconductor structure 180, and the first stress type of the plurality of through substrate vias 500 may be neutralized by the sidewall surfaces of the compound semiconductor structure 180. However when the compound semiconductor structure 180 has the hexagon-shape or other polygon-shape profiles, the second stress type may be concentrated at the side corners (having the maximum stress value) of the compound semiconductor structure 180, and the first stress type of the plurality of through substrate vias 500 may be neutralized by the side corners of the compound semiconductor structure 180. The second stress type of the compound semiconductor structure 180 with the polygon-shape profile is larger than the second stress type of the compound semiconductor structure 180 with the U-shape profile. The compound semiconductor structure 180 of the appropriate profiles may be selected according to the design requirements.

In summary, the semiconductor device of the present disclosure has the novel compound semiconductor structure surrounding the periphery of the plurality of through substrate vias. The compound semiconductor structure has the second stress type capable of neutralizing the first stress type of the plurality of through substrate vias, in order to prevent the stress of the plurality of through substrate vias from impacting other elements within the substrate and affecting the performance of the overall device. Furthermore, through the disposition of the compound semiconductor structure, the keep out zone between the plurality of through substrate vias and other elements may also be effectively scaled down, which in turn lowers the required area of the overall chip.

It should be specifically explained that the drawings of FIGS. 1-22 are for the clarity of discussion, and the structure of each element is not drawn to scale. For example, the dimension of the metal-oxide semiconductor transistor illustrated in the device area 10A (constituted by the source region 104, the drain region 106, the gate structure 200, and the gate spacer 230) is much smaller than the dimension of the plurality of through substrate vias 500 and the dimension of the compound semiconductor structure 180.

Although some embodiments of the present disclosure are disclosed above, they are not intended to limit the scope of the present disclosure. Those skilled in the art may make various changes, substitutions, and alterations herein without departing from the spirit and scope of the present disclosure. Therefore, the scope of protection should be determined through the claims.

What is claimed is:

1. An semiconductor device, comprising:
a substrate;
a source region and a drain region disposed in the substrate;
a shallow trench isolation (STI) region disposed in the substrate and surrounding the source region and the drain region;
a plurality of through substrate vias (TSV) through the substrate, wherein the plurality of through substrate vias are adjacent to the shallow trench isolation region, and the plurality of through substrate vias have a first stress type; and
a compound semiconductor structure isolating the shallow trench isolation region from the plurality of through substrate vias, wherein the compound semiconductor structure has a second stress type different from the first stress type.

2. The semiconductor device of claim 1, wherein the shallow trench isolation region defines a device area.

3. The semiconductor device of claim 2, wherein the plurality of through substrate vias are located in a peripheral area outside the device area.

4. The semiconductor device of claim 1, wherein the compound semiconductor structure is disposed in the substrate and surrounds the plurality of through substrate vias.

5. The semiconductor device of claim 1, wherein the shallow trench isolation region, the source region, the drain region, and the compound semiconductor structure extend into the substrate from a frontside surface of the substrate.

6. The semiconductor device of claim 3, further comprising a gate structure disposed on the frontside surface of the substrate and laterally between the source region and the drain region.

7. The semiconductor device of claim 6, further comprising:
an interlayer dielectric (ILD) layer located on the frontside surface of the substrate and surrounding the gate structure;
a first etch stop layer (ESL) disposed on the interlayer dielectric layer;
a first inter-metal dielectric (IMD) layer disposed on the first etch stop layer;
a second etch stop layer disposed on the first inter-metal dielectric layer; and
a second inter-metal dielectric layer disposed on the second etch stop layer.

8. The semiconductor device of claim 7, further comprising:
a source contact plug and a drain contact plug disposed through the interlayer dielectric layer, and respectively connected to the source region and the drain region;
a source contact via, a drain contact via, and a gate contact via disposed through the first inter-metal dielectric layer and the first etch stop layer, and respectively connected to the source contact plug, the drain contact plug, and the gate structure;
a source metal via, a drain metal via, and a gate metal via disposed through the second inter-metal dielectric layer and the second etch stop layer, and respectively connected to the source contact via, the drain contact via, and the gate contact via; and
a source metal layer, a drain metal layer, and a gate metal layer located in the second inter-metal dielectric layer, and respectively coupled to the source metal via, the drain metal via, and the gate metal via.

9. A method forming a semiconductor device, comprising:
providing a substrate;
forming a shallow trench isolation region, a source region, and a drain region in the substrate, wherein the shallow trench isolation region surrounds the source region and the drain region;
forming an expanded trench in the substrate, wherein the expanded trench is isolated from the source region and the drain region by the shallow trench isolation 7 region;
filling a compound semiconductor structure into the expanded trench; and
forming a plurality of through substrate vias extending into the substrate from above a frontside surface of the substrate, wherein the compound semiconductor structure surrounds the plurality of through substrate vias, wherein the plurality of through substrate vias have a first stress type, the compound semiconductor structure has a second stress type different from the first stress type.

10. The method of claim 9, wherein forming the expanded trench comprising:
sequentially forming a pad oxide layer, a hard mask layer, and a patterned photoresist layer on the frontside surface of the substrate;
patterning the hard mask layer and the pad oxide layer using the patterned photoresist layer; and
etching the substrate using the patterned pad oxide layer.

11. The method of claim 10, wherein etching the substrate comprising:
performing a dry etch process to form an initial trench; and
performing a wet etch process to expand the initial trench into the expanded trench after the dry etch process.

12. The method of claim 9, further comprising forming a cap layer on the compound semiconductor structure.

13. The method of claim 9, further comprising sequentially depositing an interlayer dielectric layer, a first etch stop layer, a first inter-metal dielectric layer, a second etch stop layer, and a second inter-metal dielectric layer on the frontside surface of the substrate.

14. The method of claim 13, wherein forming the plurality of through substrate vias comprising:
after depositing the first inter-metal dielectric layer, etching a plurality of openings through the first inter-metal dielectric layer, the first etch stop layer, and the interlayer dielectric layer, and extending into the substrate;
depositing a diffuse barrier layer on a bottom surface and sidewalls of the plurality of openings; and
forming a conductive layer filling the plurality of openings.

15. The method of claim 14, further comprising forming a metal cap layer on the diffuse barrier layer and the conductive layer.

16. The method of claim 15, further comprising:
forming a substrate metal via through the second inter-metal dielectric layer and the second etch stop layer, and connected to the metal cap layer; and
forming a substrate metal layer in the second inter-metal dielectric layer, and coupled to the substrate metal via.
